(19) United States
(12) Patent Application Publication
(10) Pub. No.: US 2026/0150562 A1
(43) Pub. Date: May 28, 2026

(54) Display Apparatus Having a Light-Emitting Device and a Pixel Lens

(71) Applicant: LG Display Co., Ltd., Seoul (KR)

(72) Inventors: Byong Hoo Kim, Paju-si (KR); Jae Bin Song, Paju-si (KR); MyungEun Song, Paju-si, (KR); WonJeong Shin, Paju-si (KR); HwaYoul Lee, Paju-si (KR)

(21) Appl. No.: 19/317,523

(22) Filed: Sep. 3, 2025

(30) Foreign Application Priority Data
Nov. 26, 2024 (KR) 10-2024-0171399

(51) Int. Cl. H10K 59/80

(52) U.S. Cl. CPC H10K 59/879; H10K 59/873; H10K 59/8792

(57) ABSTRACT

A display apparatus including a light-emitting device and a pixel lens is provided. The light-emitting device and the pixel lens can be stacked on an emission area of a device substrate. Light emitted from the light-emitting device can be focused by the pixel lens. For example, a surface of the pixel lens opposite to the device substrate can have a convex shape. A central portion of the surface of the pixel lens can have a radius of curvature different from an edge portion of the surface of the pixel lens. At least surface layer of the pixel lens can have a loss tangent (Tan δ) within a specific range. Thus, in the display apparatus, the change in the surface of the pixel lens due to the subsequent heat treatment or the deterioration compensation can be minimized. Therefore, in the display apparatus, the difference in the luminance according to a viewing angle can be reduced.

### CROSS-REFERENCE TO RELATED APPLICATIONS

This application claims the benefit of Korean Patent Application No. 10-2024-0171399, filed on Nov. 26, 2024, which is hereby incorporated by reference as if fully set forth herein.

### BACKGROUND OF THE INVENTION

### Field of the Invention

The present disclosure relates to a display apparatus in which a light-emitting device and a pixel lens are stacked on an emission area of a device substrate.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit disposed between a first electrode and a second electrode.

The light-emitting devices can be disposed on emission areas of a device substrate. Pixel lens can be disposed on the light-emitting devices. The pixel lens can overlap the light-emitting devices. Light emitted from each light-emitting device can be focused by one of pixel lenses. For example, a surface of each pixel lens opposite to the device substrate can have a convex shape.

### SUMMARY OF THE INVENTION

Accordingly, the present disclosure is directed to a display apparatus that substantially obviates one or more problems due to limitations and disadvantages of the related art.

An object of the present disclosure is to provide a display apparatus capable of reducing the difference in shapes of the pixel lenses.

Another object of the present disclosure is to provide a display apparatus capable of minimizing the reduction in the thickness of the pixel lens due to heat.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. A first light-emitting device is disposed on a first emission area of the device substrate. An optical insulating layer is disposed on the first light-emitting device. The optical insulating layer extends beyond the first emission area. A first pixel lens and a lens planarization layer are disposed on the optical insulating layer. The first pixel lens overlaps the first emission area. A first surface of the first pixel lens opposite to the device substrate has a convex shape. The first surface of the first pixel lens is covered by the lens planarization layer. A central portion of the first surface has a different curvature from an edge of the first surface. A radius of curvature at the central portion of the first surface is greater than or equal to 98.8% of a radius of curvature at the edge of the first surface.

The edge of the first surface can be disposed outside the first emission area.

A second light-emitting device can be disposed between a second emission area of the device substrate and the optical insulating layer. A second pixel lens can be disposed between the optical insulating layer and the lens planarization layer. The second pixel lens can overlap the second emission area. A second surface of the second pixel lens toward the lens planarization layer can have a convex shape. The difference in a radius of curvature between a central portion of the second surface and the central portion of the first surface can be less than or equal to 1.2% of a radius of curvature at the edge of the first surface.

The second pixel lens can include a same material as the first pixel lens.

A central portion of the second surface can have a radius of curvature same as an edge of the second surface.

The edge of the second surface can have the radius of curvature same as the edge of the first surface.

An upper barrier pattern can be disposed between the optical insulating layer and the lens planarization layer. The upper barrier pattern can be disposed outside the first emission area. The edge of the first surface can overlap the upper barrier pattern.

An encapsulation structure can be disposed between the device substrate and the optical insulating layer. The first light-emitting device can be covered by the encapsulation structure. A lower barrier pattern can be disposed between the encapsulation and the optical insulating layer. The lower barrier pattern can overlap the upper barrier pattern. The lower barrier pattern can include a different material from the upper barrier pattern.

In another embodiment, there is provided a display apparatus comprising a device substrate. A light-emitting device is disposed on an emission area of the device substrate. An optical insulating layer is disposed on the light-emitting device. The optical insulating layer extends beyond the emission area. A pixel lens and a lens planarization layer are disposed on the optical insulating layer. The pixel lens includes a region overlapping with the emission area. The pixel lens can be covered by a lens planarization layer. The pixel lens includes a lens layer and a surface layer. The lens layer has a convex shape toward the lens planarization layer. The surface layer is disposed between the lens layer and the lens planarization layer. The surface layer has a loss tangent (Tan δ) of 0.051 to 0.058.

A thickness of the surface layer can be smaller than a thickness of the lens layer.

The lens layer can include a different material from the surface layer.

A loss tangent of the lens layer can be different from the loss tangent of the surface layer.

A thickness of the surface layer at a central portion of the pixel lens can be smaller than a thickness of the surface layer at an edge portion of the pixel lens.

A curvature of the lens layer at the central portion of the pixel lens can be the same as a curvature of the lens layer at the edge portion of the pixel lens.

The difference in a radius of curvature between the surface layer and the lens layer at the central portion of the pixel lens can be 0.8% to 1.2% of the difference in a radius of curvature between the surface layer and the lens layer at the edge of the pixel lens.

In still another embodiment, a display apparatus comprises: a first light-emitting device on a first emission area of a device substrate; an optical insulating layer on the first light-emitting device, the optical insulating layer extending beyond the first emission area; upper barrier patterns on the optical insulating layer; and a first pixel lens on the optical insulating layer of the first emission area, a first surface of the first pixel lens opposite to the device substrate having a convex shape; and wherein a central portion of the first surface of the first pixel lens has a different curvature from an edge of the first surface of the first pixel lens, and wherein an edge of the first surface of the first pixel lens extends beyond an edge of one of the upper barrier patterns to overlap the one of the upper barrier pattern.

In still another embodiment, the edge of the first surface of the first pixel lens is in direct contact with a top surface of the one of the upper barrier patterns.

In still another embodiment, the display apparatus may further comprises: an encapsulation structure between the device substrate and the optical insulating layer, the encapsulation structure covering the first light-emitting device; and a lower barrier pattern between the encapsulation structure and the optical insulating layer, the lower barrier pattern overlapping with the upper barrier pattern, wherein the lower barrier pattern includes a different material from the upper barrier pattern.

In still another embodiment, a radius of curvature at a central portion of the first surface of the first pixel lens is smaller than a radius of curvature at the edge of the first surface of the first pixel lens.

In still another embodiment, the upper barrier pattern comprises a black dye, and the first pixel lens comprises a polymer material including at least one of a polyester resin, an acrylic resin, a polyurethane resin, a melamine resin, a polyvinyl alcohol resin, and an oxazoline resin.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is an enlarged view of K1 region in FIG. 1;

FIG. 4 is a view showing a cross-section taken along line I-I′ of FIG. 3;

FIG. 5 is an enlarged view of R1 region in FIG. 4;

FIGS. 6 to 10 are photographs schematically showing a shape of a pixel lens according to a loss tangent (Tan δ); and

FIGS. 11 to 19 are views showing the display apparatus according to another embodiment of the present disclosure.

### DETAILED DESCRIPTION OF THE INVENTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical spirit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

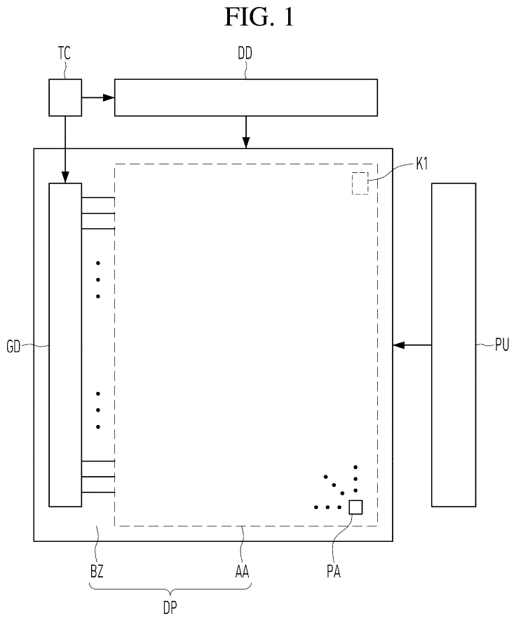

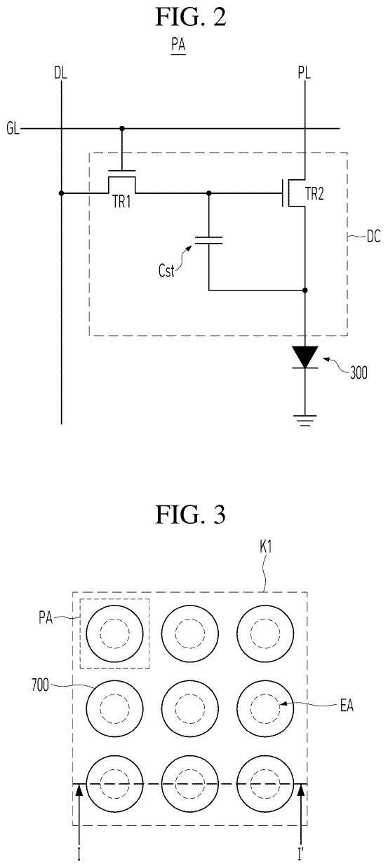

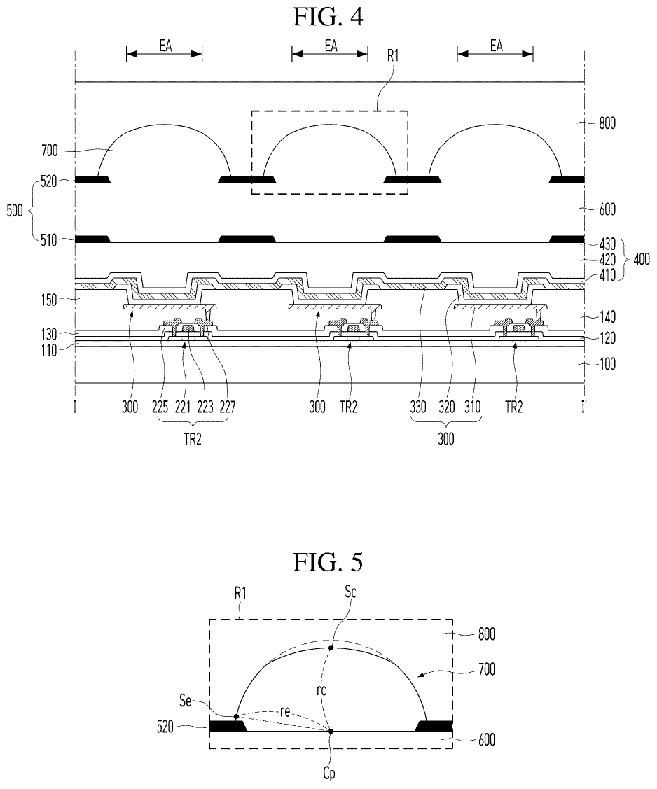

FIG. 1 is a view schematically showing a display apparatus according to an embodiment of the present disclosure. FIG. 2 is a view showing a circuit of a pixel area in the display apparatus according to the embodiment of the present disclosure. FIG. 3 is an enlarged view of K1 region in FIG. 1. FIG. 4 is a view showing a cross-section taken along line I-I′ of FIG. 3.

Referring to FIGS. 1 to 4, the display apparatus according to the embodiment of the present disclosure can include a display panel DP. The display panel DP can generate an image provided to a user. For example, pixel areas PA can be disposed within the display panel DP. Various signals can be applied in each pixel area PA through signal wirings GL, DL and PL. The signal wirings GL, DL and PL can include a gate line GL applying a gate signal, a data line DL applying a data signal, and a power voltage supply line PL supplying a power voltage.

The display panel DP can include an active area AA in which the pixel areas PA are disposed and a bezel area BZ disposed outside the active area AA. Each of the wirings GL, DL and PL can apply a signal to the pixel areas PA through the bezel area BZ. For example, the active area AA can be surrounded by the bezel area BZ. A gate driver GD electrically connected to the gate line GL, a data driver DD electrically connected to the data line DL, a power unit PU electrically connected to the power voltage supply line PL, and a timing controller TC controlling the gate driver GD and the data driver DD can be disposed outside the active area AA. At least one of the gate driver GD, the data driver DD, the timing controller TC and the power unit PU can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color according to a signal applied through the signal wirings GL, DL and PL. For example, a driving circuit DC electrically connected to the signal wirings GL, DL and PL, and a light-emitting device 300 electrically connected to the driving circuit DC can be disposed in each pixel area PA. The driving circuit DC can supply a driving current corresponding to the data signal to the light-emitting device 300 according to the gate signal using the power voltage for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include an oxide semiconductor, such as IGZO. The second semiconductor pattern 221 can include a drain region, a channel region and a source region. The channel region can be disposed between the drain region and the source region. The drain region and the source region can have a resistance smaller than the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The drain region and the source region of the second semiconductor pattern 221 can be disposed outside the second gate electrode 223. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be electrically connected to the drain region of the second semiconductor pattern 221. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can be insulated from the second gate electrode 223. For example, the second drain electrode 225 can be disposed on a different layer from the second gate electrode 223. The second drain electrode 225 can include a different material from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be electrically connected to the source region of the second semiconductor pattern 221. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can be insulated from the second gate electrode 223. For example, the second source electrode 227 can be disposed on a different layer from the second gate electrode 223. The second source electrode 227 can include a different material from the second gate electrode 223. The second source electrode 227 can include a same material as the second drain electrode 225. For example, the second source electrode 227 can be disposed on a same layer as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of the signal applied to the second gate electrode 223 for one frame. The storage capacitor Cst can have a stacked structure of capacitor electrodes. For example, the storage capacitor Cst can include a first capacitor electrode electrically connected to the second gate electrode 233 and a second capacitor electrode electrically connected to the second source electrode 227. The storage capacitor Cst can be formed using a process of forming the first thin film transistor TR1 and the second thin film transistor TR2. For example, the first capacitor electrode can be formed simultaneously with the second gate electrode 223, and the second capacitor electrode can be formed simultaneously with the second source electrode 227.

The driving circuit DC of each pixel area PA can be supported by a device substrate 100. The device substrate 100 can include an insulating material. For example, the device substrate 100 can include glass or plastic. At least one insulating layers 110, 120, 130, 140 and 150 for preventing unnecessary electrical connection can be disposed on the device substrate 100. For example, a buffer insulating layer 110, a gate insulating layer 120, an interlayer insulating layer 130, a device planarization layer 140 and a bank insulating layer 150 can be disposed on the device substrate 100.

The buffer insulating layer 110 can be disposed close to the device substrate 100. The buffer insulating layer 110 can prevent pollution due to the device substrate 100 in a process of forming the driving circuit DC of each pixel area PA. For example, an upper surface of the device substrate 100 toward the driving circuit DC of each pixel area PA can be covered by the buffer insulating layer 110. The first thin film transistor TR1, the second thin film transistor TR2 and the storage capacitor Cst of each pixel area PA can be disposed on the buffer insulating layer 110. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can be an inorganic insulating layer made of an inorganic insulating material, such as silicon oxide (SiOx) and silicon nitride (SiNx).

The interlayer insulating layer 130 can be disposed on the gate insulating layer 120. The second drain electrode 225 and the second source electrode 227 of each pixel area PA can be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can be an inorganic insulating layer made of an inorganic insulating material.

The device planarization layer 140 can be disposed on the interlayer insulating layer 130. The device planarization layer 140 can remove the thickness difference due to the driving circuit DC of each pixel area PA. For example, the first drain electrode, the first source electrode, the second drain electrode 225 and the second source electrode 227 of each pixel area PA can be covered by the device planarization layer 140. An upper surface of the device planarization layer 140 opposite to the device substrate 100 can be flat. For example, the upper surface of the device planarization layer 140 can be parallel to the upper surface of the device substrate 100. The device planarization layer 140 can include an insulating material. The device planarization layer 140 can include a material having a relative high fluidity. For example, the device planarization layer can be an organic insulating layer made of an organic insulating material.

The bank insulating layer 150 can be disposed on the device planarization layer 140. The bank insulating layer 150 can include an insulating material. For example, the bank insulating layer 150 can be an organic insulating layer made of an organic insulating material. The bank insulating layer 150 can include a different material from the device planarization layer 140. The bank insulating layer 150 can define an emission area EA in each pixel area PA. For example, portions of the upper surface of the device planarization layer 140 overlapping with the emission area EA of each pixel area PA can be exposed by the bank insulating layer 150.

The light-emitting device 300 of each pixel area PA can be disposed on the device planarization layer 140. The light-emitting device 300 of each pixel area PA can emit light displaying a specific color by using the driving current. For example, the light-emitting device 300 of each pixel area PA can have a stacked structure of a first electrode 310, a light-emitting unit 320, and a second electrode 330. The light-emitting device 300 of each pixel area PA can overlap the emission area EA of the corresponding pixel area PA. For example, the first electrode 310, the light-emitting unit 320 and the second electrode 330 of each pixel area PA can be sequentially stacked on a portion of the upper surface of the device planarization layer 140 overlapping with the emission area EA of the corresponding pixel area PA exposed by the bank insulating layer 150.

The first electrode 310 can include a conductive material. The first electrode 310 can include a material having relative high reflectance. For example, the first electrode 310 can include a metal, such as aluminum (Al) and silver (Ag). The first electrode 310 can have a multi-layer structure. For example, the first electrode 310 can have a structure in which a reflective electrode made of a metal is disposed between transparent electrodes made of a transparent conductive material, such as ITO and IZO.

The light-emitting unit 320 can generate light having luminance corresponding to the voltage difference between the first electrode 310 and the second electrode 330. For example, the light-emitting unit 320 can include an emission material layer (EML). The emission material layer can include an organic emission material, an inorganic emission material, or a hybrid emission material. For example, the display apparatus according to the embodiment of the present disclosure can be an organic light-emitting display apparatus including an organic emission material.

The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 320 can be improved.

The second electrode 330 can include a conductive material. The second electrode 330 can include a different material from the first electrode 310. For example, the transmittance of the second electrode 330 can be greater than the transmittance of the first electrode 310. For example, the second electrode 330 can be a transparent electrode made of a transparent conductive material, such as ITO and IZO. Thus, in the display apparatus according to the embodiment of the present disclosure, the light generated by the light-emitting unit 320 can be emitted outside through the second electrode 330. The second electrode 330 can have a work-function different from the first electrode 310. For example, the work-function of the second electrode 330 can be smaller than the work-function of the first electrode 310. Thus, in the display apparatus according to the embodiment of the present disclosure, the first electrode 310 can be function as anode, and the second electrode 330 can be function as cathode.

The driving current generated by the driving circuit DC of each pixel area PA can be applied to the first electrode 310 of the corresponding pixel area PA. For example, the first electrode 310 of each pixel area PA can be in direct contact with the second source electrode 227 of the corresponding pixel area PA by penetrating the device planarization layer 140. A connection point between the first electrode 310 and the second source electrode 227 in each pixel area PA can be disposed outside the emission area EA defined in the corresponding pixel area PA. For example, a portion of the first electrode 310 overlapping with the emission area EA in each pixel area PA can be in direct contact with the upper surface of the device planarization layer 140. Thus, in the display apparatus according to the embodiment of the present disclosure, the deviation in the location of the first electrode 310 in the emission area EA of each pixel area PA can be minimized. Therefore, in the display apparatus according to the embodiment of the present disclosure, the deviation in the luminance of the light emitted from the emission area EA of each pixel area PA due to the generating location can be prevented.

The bank insulating layer 150 can partially expose the first electrode 310 of each pixel area PA. The first electrode 310 of each pixel area PA can be insulated from the first electrode 310 of adjacent pixel area PA by the bank insulating layer 150. For example, an edge of the first electrode 310 in each pixel area PA can be covered by the bank insulating layer 150. The light-emitting unit 320 can be in direct contact with the first electrode 310 and the second electrode 330 in the emission area EA of each pixel area PA. Thus, in the display apparatus according to the embodiment of the present disclosure, the light can be generated and emitted only in the emission area EA of each pixel area PA. A region disposed between the emission areas EA of the pixel areas PA can be defined as a non-emission area. For example, a portion of the device planarization layer 140 overlapping with the non-emission area can be covered by the bank insulating layer 150.

An image realized by the pixel areas PA can include various colors. For example, the emission area EA of each pixel area PA can be one of a blue emission area realizing a blue color, a green emission area realizing a green color, and a red emission area realizing a red color. The light emitted from the light-emitting device 300 of each pixel area PA can display a different color from the light emitted from the light-emitting device 300 of adjacent pixel area PA. The light-emitting unit 320 of each pixel area PA can be spaced apart from the light-emitting unit 320 of adjacent pixel area PA on the bank insulating layer 150.

A signal applied to the second electrode 330 of each pixel area PA can be a same as a signal applied to the second electrode 330 of adjacent pixel area PA. For example, the second electrode 330 of each pixel area PA can be electrically connected to the second electrode 330 of adjacent pixel area PA. The second electrode 330 of each pixel area PA can include a same material as the second electrode 330 of adjacent pixel area PA. The second electrode 330 of each pixel area PA can be formed by a same process as the second electrode of adjacent pixel area PA. For example, the second electrode 330 of each pixel area PA can be formed simultaneously with the second electrode 330 of adjacent pixel area PA. Thus, in the display apparatus according to the embodiment of the present disclosure, a process of forming the second electrode 330 in each pixel area PA can be simplified. The second electrode 330 of each pixel area PA can be in direct contact with the second electrode 330 of adjacent pixel area PA.

An encapsulation structure 400 can be disposed on the light-emitting device 300 of each pixel area PA. The encapsulation structure 400 can prevent the damage of the light-emitting device 300 in each pixel area PA due to external impact and moisture. The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. The second encapsulating layer 420 can include a material having a relative high fluidity. For example, the first encapsulating layer 410 and the third encapsulating layer 430 can be an inorganic insulating layer made of an inorganic insulating material, and the second encapsulating layer 420 can be an organic insulating layer made of an organic insulating material. A thickness difference due to the light-emitting device 300 of each pixel area PA can be removed by the second encapsulating layer 420. For example, an upper surface of the encapsulation structure 400 opposite to the device substrate 100 can be flat. The second encapsulating layer 420 can be surrounded by the first encapsulating layer 410 and the third encapsulating layer 430.

A barrier structure 500 can be disposed on the encapsulation structure 400. The barrier structure 500 can limit a travelling direction of the light emitted from the light-emitting device 300 of each pixel area PA. Thus, in the display apparatus according to the embodiment of the present disclosure, the unintended color mixing can be prevented. The barrier structure 500 can have a multi-layer structure. For example, the barrier structure 500 can have a stacked structure of a lower barrier pattern 510 and an upper barrier pattern 520.

The lower barrier pattern 510 can be disposed close to the encapsulation structure 400. For example, the lower barrier pattern 510 can be in direct contact with the upper surface of the encapsulation structure 400. The lower barrier pattern can include a material capable of blocking light. The lower barrier pattern 510 can include an insulating material. For example, the lower barrier pattern 510 can include a black dye, such as carbon black. The lower barrier pattern 510 can overlap the bank insulating layer 150. The lower barrier pattern 510 can't overlap the emission area EA of each pixel area PA. For example, the lower barrier pattern 510 can be disposed within the non-emission area. Portions of the upper surface of the encapsulation structure 400 overlapping with the emission area EA of each pixel area PA can be exposed by the lower barrier pattern 510.

The upper barrier pattern 520 can be disposed on the lower barrier pattern 510. The upper barrier pattern 520 can be spaced apart from the lower barrier pattern 510. The upper barrier pattern 520 can be disposed on a different layer from the lower barrier pattern 510. For example, an optical insulating layer 600 covering the lower barrier pattern 510 can be disposed on the encapsulation structure 400, and the upper barrier pattern 520 can be disposed on the optical insulating layer 600.

The optical insulating layer 600 can include an insulating material. The optical insulating layer 600 can include a material having a relative high transmittance. For example, the optical insulating layer 600 can include an organic insulating material and/or an inorganic insulating material. The thickness difference due to the lower barrier pattern 510 can be removed by the optical insulating layer 600. For example, the upper surface of the optical insulating layer 600 opposite to the device substrate 100 can be flat.

The optical insulating layer 600 can extend onto the emission area EA of each pixel area PA. For example, the portions of the upper surface of the encapsulation structure 400 exposed by the lower barrier pattern 510 can be in direct contact with the optical insulating layer 600. For example, the optical insulating layer can include a region overlapping with the emission area EA of each pixel area PA and a region overlapping with the lower barrier pattern 510. The lower barrier pattern 510 can be in direct contact with the optical insulating layer 600 within the non-emission area. Thus, in the display apparatus according to the embodiment of the present disclosure, the light generated by the light-emitting unit 320 of each pixel area PA can be emitted by passing through a portion of the optical insulating layer 600. That is, in the display apparatus according to the embodiment of the present disclosure, the optical distance of the light emitted from the light-emitting device 300 of each pixel area PA can be proportional to a thickness of the optical insulating layer 600. Therefore, in the display apparatus according to the embodiment of the present disclosure, the light emitted from the light-emitting device 300 of each pixel area PA can have a sufficient optical distance.

The upper barrier pattern 520 can be disposed close to the optical insulating layer 600. For example, the upper barrier pattern 520 can be in direct contact with the upper surface of the optical insulating layer 600. The upper barrier pattern 520 can include a material capable of blocking light. The upper barrier pattern 520 can include an insulating material. For example, the upper barrier pattern 520 can include a black dye, such as black carbon. The upper barrier pattern 520 can include a same material as the lower barrier pattern 510.

The upper barrier pattern 520 can overlap the lower barrier pattern 510. For example, the upper barrier pattern 520 can overlap the bank insulating layer 150. The upper barrier pattern 520 can be disposed within the non-emission area. The upper barrier pattern 520 can't overlap the emission area EA of each pixel area PA. A portion of the upper surface of the optical insulating layer 600 overlapping with the emission area EA of each pixel area PA can be exposed by the upper barrier pattern 520.

The lower barrier pattern 510 can have a smaller size than the bank insulating layer 150. For example, the portions of the encapsulation structure 400 exposed by the lower barrier pattern 510 can have a larger size than the emission area EA of one of the pixel areas PA. A size of the upper barrier pattern 520 can have a same as a size of the lower barrier pattern 510. For example, the upper barrier pattern 520 can have a same width as the lower barrier pattern 510. Thus, in the display apparatus according to the embodiment of the present disclosure, the emission area EA of each pixel area PA can have a smaller size than one of portions of the optical insulating layer 600 exposed by the upper barrier pattern 520. Therefore, in the display apparatus according to the embodiment of the present disclosure, the light extraction efficiency of the emission area EA defined in each pixel area PA can be improved.

Pixel lenses 700 can be disposed on the portions of the optical insulating layer 600 exposed by the upper barrier pattern 520. For example, each of the pixel lenses 700 can overlap the emission area EA of one of the pixel areas PA. The light emitted from the light-emitting device 300 of each pixel area PA can pass through one of the pixel lenses 700. The pixel lens 700 disposed on each pixel area PA can have a larger size than the emission area EA defined in the corresponding pixel area PA. For example, an edge of each pixel lens 700 can overlap the upper barrier pattern 520. Thus, in the display apparatus according to the embodiment of the present disclosure, the light extraction efficiency can be effectively improved.

A lower surface of each pixel lens 700 toward the device substrate 100 can be in direct contact with the upper surface of the optical insulating layer 600 and the upper barrier pattern 520. A surface of each pixel lens 700 opposite to the device substrate 100 can have a convex shape. For example, each of the pixel lenses 700 can function as a convex lens. The light emitted from the light-emitting device 300 of each pixel area PA can be focused by the pixel lens 700 of the corresponding pixel area PA. Thus, in the display apparatus according to the embodiment of the present disclosure, the frontal luminance of each pixel PA can be improved. Therefore, in the display apparatus according to the embodiment of the present disclosure, the afterimage of the image can't occur in the inclined direction.

A plane of the pixel lens 700 on each pixel area PA can have a shape corresponding to a plane of the emission area EA defined in the corresponding pixel area PA. For example, the emission area EA and the pixel lens 700 of each pixel area can have a planar shape of a circular. Thus, in the display apparatus according to the embodiment of the present disclosure, the light emitted from the light-emitting device 300 of each pixel area PA can be focused uniformly.

Each of the pixel lenses 700 can include a polymer material. For example, each of the pixel lenses 700 can include at least one of a polyester resin, an acrylic resin, a polyurethane resin, a melamine resin, a polyvinyl alcohol resin, and an oxazoline resin. Each of the pixel lenses 700 can be formed simultaneously with adjacent pixel lens 700. For example, a process of forming the pixel lenses 700 can include a step of forming a lens material layer on the upper barrier pattern 520 and the optical insulating layer 600, a step of forming lens patterns overlapping with emission areas EA of the pixel areas PA by removing a portion of the lens material layer overlapping with the non-emission area, and a step of forming the pixel lenses 700 overlapping with the emission areas EA of the pixel areas PA by reflowing the lens patterns.

Each of the pixel lenses 700 can include a multifunctional monomer for surface curing. The multifunctional monomer for surface curing can include at least one of butylene glycol dimethacrylate and pentaerythritol tetraacrylate. Thus, in the display apparatus according to the embodiment of the present disclosure, each of the pixel lenses 700 can have the loss tangent (Tan δ) within a specific range.

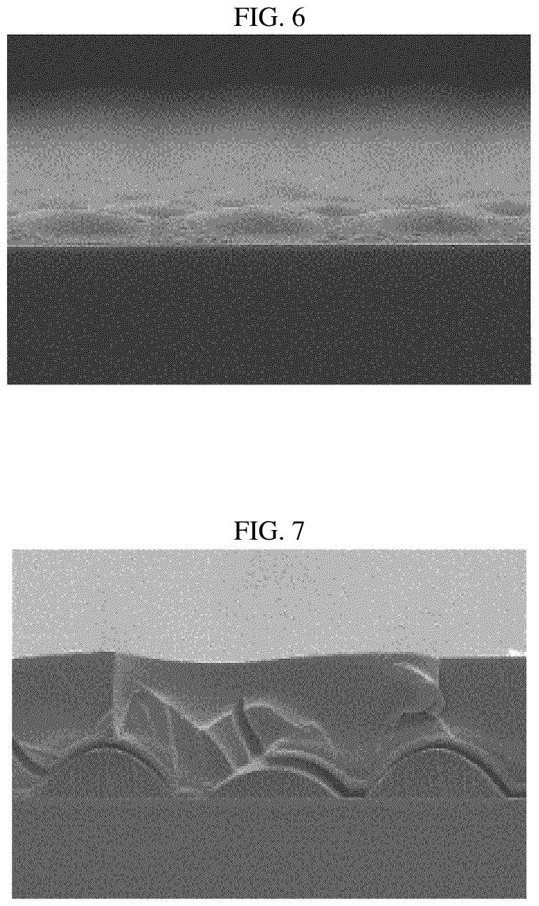

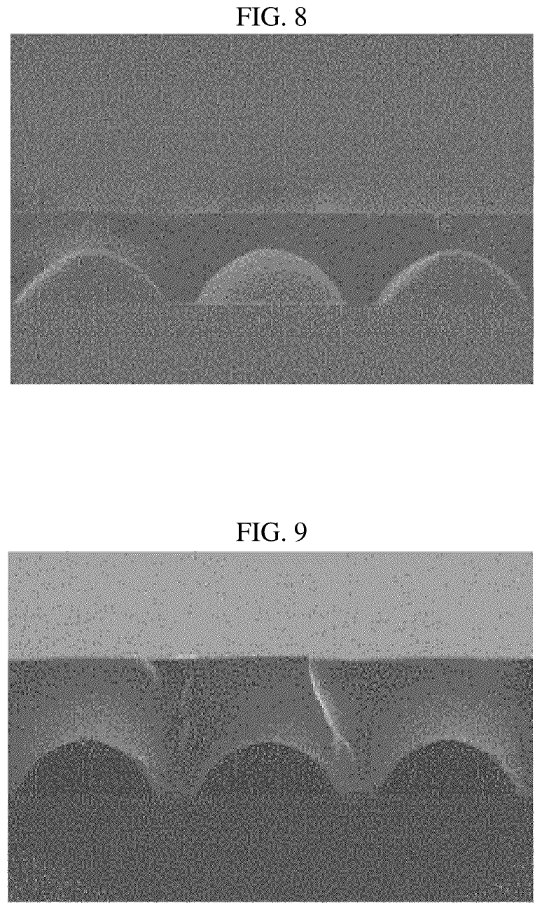

The below Table 1 can disclose the difference in the thickness due to the subsequent heat treatment or the deterioration compensation in a first lens \textcircled{1} having the loss tangent of 0.034, a second lens \textcircled{2} having the loss tangent of 0.045, a third lens \textcircled{3} having the loss tangent of 0.051, a fourth lens \textcircled{4} having the loss tangent of 0.058, and a fifth lens \textcircled{5} having the loss tangent of 0.065. FIG. 6 is a photograph schematically showing a shape of the first lens \textcircled{1} after the subsequent heat treatment and the deterioration compensation. FIG. 7 is a photograph schematically showing a shape of the second lens \textcircled{2} after the subsequent heat treatment and the deterioration compensation. FIG. 8 is a photograph schematically showing a shape of the third lens \textcircled{3} after the subsequent heat treatment and the deterioration compensation. FIG. 9 is a photograph schematically showing a shape of the fourth lens \textcircled{4} after the subsequent heat treatment and the deterioration compensation. FIG. 10 is a photograph schematically showing a shape of the fifth lens \textcircled{5} after the subsequent heat treatment and the deterioration compensation. Herein, the subsequent heat treatment can include an aging process to stabilize the shape of the pixel lens, and the deterioration compensation can include a process of applying UV or heat to the pixel lenses to improve the afterimage.

TABLE 1

| | first | second | third | fourth | fifth |
|---|---|---|---|---|---|
| | lens \textcircled{1} | lens \textcircled{2} | lens \textcircled{3} | lens \textcircled{4} | lens \textcircled{5} |
| initial | 8.98 μm | 9.34 μm | 8.50 μm | 9.16 μm | 9.27 μm |
| thickness | | | | | |
| final | 7.50 μm | 8.68 μm | 8.40 μm | 9.09 μm | — |
| thickness | | | | | |
| Thickness | 16.5% | 7.1% | 1.2% | 0.8% | — |
| reduction | | | | | |
| rate | | | | | |

Referring to Table 1 and FIGS. 6 to 10, the first lens \textcircled{1} which the thickness is relatively greatly reduced can't maintain the shape of the lens, the second lens \textcircled{2} and the fifth lens \textcircled{5} can't function as a normal lens due to the occurrence of crack, but the third lens \textcircled{3} and the fourth lens \textcircled{4} which the reduction in the thickness is minimized can maintain a lens shape, without the occurrence of the crack. That is, in the display apparatus according to the embodiment of the present disclosure, each of the pixel lenses 700 can have the loss tangent (Tan δ) of 0.051 to 0.058. Thus, in the display apparatus according to the embodiment of the present disclosure, the reduction in the thickness of the pixel lenses 700 due to the subsequent heat treatment and/or the deterioration compensation can be minimized. And, in the display apparatus according to the embodiment of the present disclosure, the difference in the shape of the pixel lenses 700 due to the subsequent heat treatment and/or the deterioration compensation can be reduced. Therefore, in the display apparatus according to the embodiment of the present disclosure, the quality of the image recognized by the user can be improved.

FIG. 5 is an enlarged view of R1 region in FIG. 4. As shown in FIG. 5, the center thickness of each pixel lens 700 can be reduced by the subsequent heat treatment and/or the deterioration compensation, but the edge thickness of each pixel lens 700 can't be reduced. That is, in the display apparatus according to the embodiment of the present disclosure, the surface of each pixel lens having a convex shape can include an edge portion Se disposed close to the upper barrier pattern 520 and a central portion Sc corresponding to the center of the corresponding pixel lens 700, and a radius rc of curvature at the central portion Sc can be made smaller than a radius Re of curvature at the edge portion Se by heat. Thus, in the display apparatus according to the embodiment of the present disclosure, the curvature of the central portion Sc can be made larger than the curvature of the edge portion Se by heat. Referring to Table 1, the final thickness of the pixel lens 700 having the loss tangent (Tan δ) of 0.051 to 0.058 can be reduced by 0.8% to 1.2% based on the initial thickness of the corresponding pixel lens 700 by heat. Therefore, in the display apparatus according to the embodiment of the present disclosure, the radius rc of curvature at the central portion Sc can be 98.8% to 99.2% of the radius re of curvature at the edge portion Se after the subsequent heat treatment and the degradation compensation. For example, in the display apparatus according to the embodiment of the present disclosure, the central portions Sc of the pixel lenses 700 can have the difference in the thickness of 0.8% to 1.2%.

As shown in FIG. 4, a lens planarization layer 800 can be disposed on the pixel lenses 700. The lens planarization layer 800 can prevent the damage of the pixel lenses 700 due to the external impact. For example, each of the pixel lenses 700 can be completely covered by the lens planarization layer 800. The lens planarization layer 800 can extend beyond the emission area EA defined in each pixel area PA. The lens planarization layer 800 can include an insulating material. The lens planarization layer 800 can include a transparent material. For example, the lens planarization layer 800 can include an organic insulating material and/or an inorganic insulating material. An upper surface of the lens planarization layer 800 opposite to the device substrate 100 can be flat.

A surface of each pixel lens 700 having a convex shape can be in direct contact with the lens planarization layer 800. A refractive index of the lens planarization layer 800 can be smaller than a refractive index of each pixel lens 700. Thus, in the display apparatus according to the embodiment of the present disclosure, the light passing through each pixel lens 700 can't be reflected toward the device substrate 100 at a boundary between the corresponding pixel lens 700 and the lens planarization layer 800. Therefore, in the display apparatus according to the embodiment of the present disclosure, the light extraction efficiency can be improved.

Accordingly, the display apparatus according to the embodiment of the present disclosure can include the light-emitting devices 300 on the emission areas EA of the device substrate 100, the optical insulating layer 600 on the light-emitting devices 300, the pixel lenses 700 on the optical insulating layer 600, the lens planarization layer 800 on the pixel lenses 700, and the barrier structure 500 on the non-emission area of the device substrate 100, wherein each of the pixel lenses 700 overlapping with the emission areas EA can have a convex shape toward the lens planarization layer 800, and wherein each of the pixel lenses 700 can have the loss tangent (Tan δ) of 0.051 to 0.058. Thus, in the display apparatus according to the embodiment of the present disclosure, the deformation in the shape of each pixel lens 700 due to the subsequent heat treatment or the deterioration compensation can be minimized. Therefore, in the display apparatus according to the embodiment of the present disclosure, the quality of the image recognized by the user can be improved.

And, in the display apparatus according to the embodiment of the present disclosure, the difference in the shape of each pixel lens 700 due to the subsequent heat treatment or the deterioration compensation can be reduced. Furthermore, in the display apparatus according to the embodiment of the present disclosure, the damage of the pixel lenses 700 due to crack can be prevented. Thus, in the display apparatus according to the embodiment of the present disclosure, the occurrence of spots due to the difference in the shape of the pixel lenses 700 can be prevented. Also, in the display apparatus according to the embodiment of the present disclosure, the occurrence of the afterimage recognized by the user located in the inclined direction can be significantly reduced. Therefore, in the display apparatus according to the embodiment of the present disclosure, the power consumed for compensating the difference in the shape of the pixel lenses 700 can be reduced, and low power driving can be possible.

The display apparatus according to the embodiment of the present disclosure is described such that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor pattern. The third gate electrode of each pixel area PA can be electrically connected to the gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

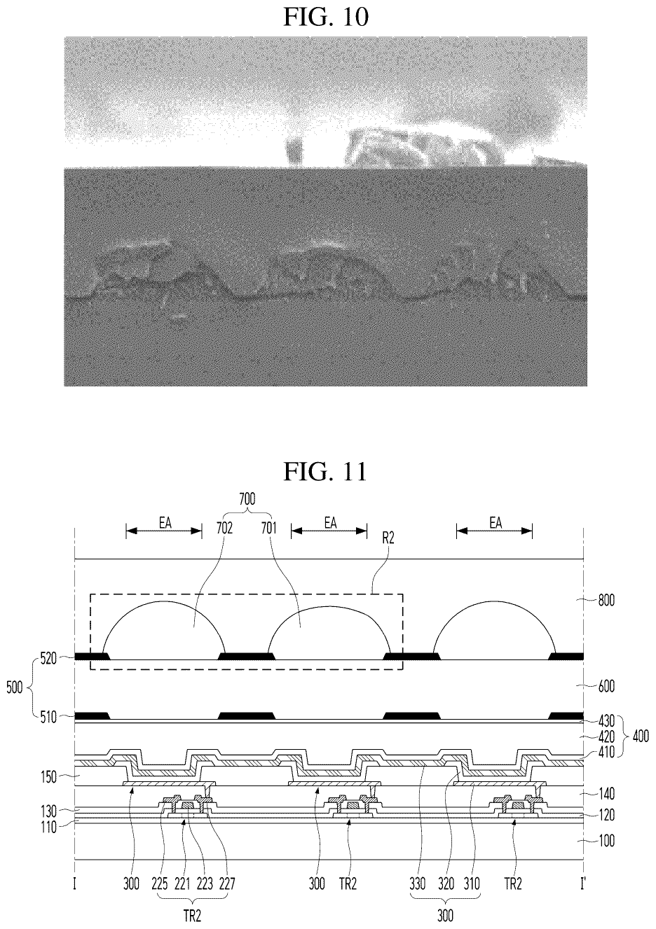

The display apparatus according to the embodiment of the present disclosure is described such that deterioration compensation is performed on all pixel lenses 700. However, in the display apparatus according to another embodiment of the present disclosure, only some of the pixel lenses 700 can be compensated for deterioration. For example, in the display apparatus according to another embodiment of the present disclosure, the pixel lenses 700 can include a first pixel lens 701 in which the center thickness is reduced by deterioration compensation and a second pixel lens 702 which is not compensated for deterioration, as shown in FIGS. 11 and 12.

The first pixel lens 701 can include a first surface 701s having a convex shape toward the lens planarization layer 800. The first surface 701s can include a first edge portion Se1 disposed close to the upper barrier pattern 520 and a first central portion Sc1 corresponding to the center of the first pixel lens 701. The curvature of the first central portion Sc1 can be larger than the curvature of the first edge Se1. The radius r1 of curvature at the first central portion Sc1 can be smaller than the radius Re of curvature at the first edge portion Se1.

The second pixel lens 702 can include a same material as the first pixel lens 701. For example, the loss tangent (Tan δ) of the second pixel lens 702 can be 0.051 to 0.058. A second surface 702s of the second pixel lens 702 having a convex shape toward the lens planarization layer 800 can include a second edge portion Se2 disposed close to the upper barrier pattern 520 and a second central portion Sc2 corresponding to the center of the second pixel lens 702.

The curvature of the second edge portion Se2 can be same as the curvature of the first edge portion Se1. For example, the second edge portion Se2 can have a radius of curvature same as the first edge portion Se1. The curvature of the second central portion Sc2 can be a same as the curvature of the second edge portion Se2. For example, a radius r2 of curvature at the second central portion Sc2 can be a same as the radius of curvature at the first edge portion Se1. The second central portion Sc2 can have a different curvature from the first central portion Sc1. For example, the radius r2 of curvature at the second central portion Sc2 can be greater than the radius r1 of curvature at the first central portion Sc1. The radius r1 of curvature at the first central portion SC1 can be greater than or equal to 98.8% of the radius r2 of curvature at the second central portion Sc2. For example, the difference in the radius of curvature between the first central portion Sc1 and the second central portion Sc2 can be less than or equal to 1.2% of the radius of the curvature at the first edge portion Se1. Thus, in the display apparatus according to another embodiment of the present disclosure, the difference in the shape of the pixel lenses 700 due to partial deterioration compensation can be significantly reduced. Therefore, in the display apparatus according to another embodiment of the present disclosure, the occurrence of the spots due to the difference in the shape of the pixel lenses 700 can be effectively prevented. And, in the display apparatus according to another embodiment of the present disclosure, deterioration in the quality of the image recognized by the user can be minimized, and the occurrence of afterimage can be prevented.

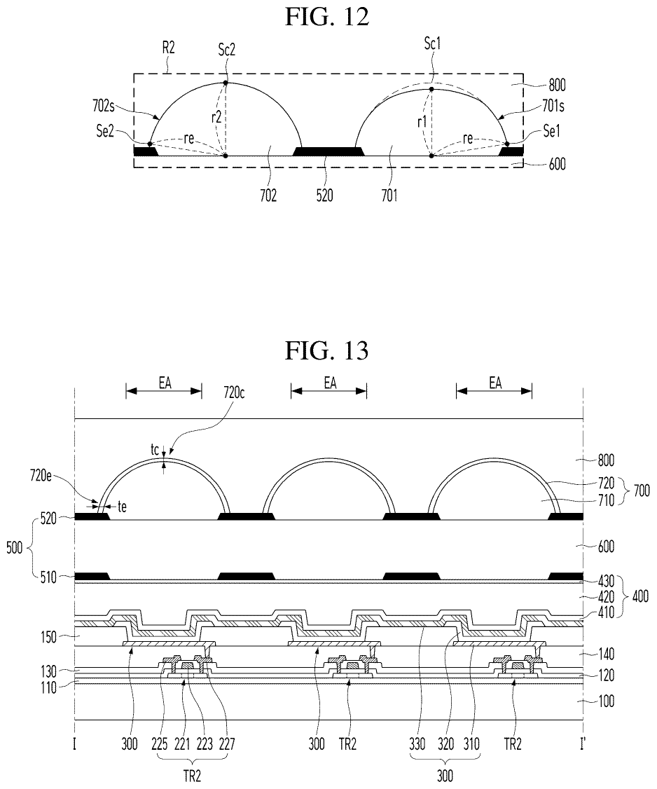

The display apparatus according to the embodiment of the present disclosure is described such that each of the pixel lenses 700 has a single layer structure. However, in the display apparatus according to another embodiment of the present disclosure, each of the pixel lenses 700 can have a multi-layer structure. For example, in the display apparatus according to another embodiment of the present disclosure, each of the pixel lenses 700 can have a stacked structure of a lens layer 710 and a surface layer 720, as shown in FIG. 13.

The lens layer 710 can be disposed close to the optical insulating layer 600. For example, the upper surface of the optical insulating layer 600 can be in direct contact with a lower surface of the lens layer 710 toward the device substrate 100. A surface of the lens layer 710 opposite to the device substrate 100 can have a convex shape. The surface layer 720 can be disposed on the surface of the lens layer 710 having a convex shape. For example, the surface layer 720 can be in direct contact with the surface of the lens layer 710 having a convex shape. The surface layer 720 can include a different material from the lens layer 710. For example, the lens layer 710 can't include a multifunctional monomer for surface curing. The loss tangent (Tan δ) of the lens layer 710 can be different from the loss tangent of the surface layer 720.

The surface layer 720 can have a smaller thickness than the lens layer 710. For example, the surface layer 720 can have a linear layer shape extending along the surface of the lens layer 710 having a convex shape. The surface layer 720 can be in direct contact with the upper barrier pattern 520 at the outside of the lens layer 710. For example, the surface of the lens layer 710 having a convex shape can be completely covered by the surface layer 720. Thus, in the display apparatus according to another embodiment of the present disclosure, the change in the shape of the lens layer 710 due to the subsequent heat treatment and/or the deterioration compensation can be prevented by the surface layer 720. For example, the surface of the lens layer 710 having a convex shape can be a same curvature. A thickness tc of a first portion 720c of the surface layer 720 disposed at the central portion can be reduced by heat. For example, the thickness tc of the first portion 720c of the surface layer 720 disposed at the central portion can be a smaller than a thickness te of a second portion 720e of the surface layer 720 disposed at the edge portion. The difference in the radius of curvature between the lens layer 710 and the surface layer 720 at the central portion of the pixel lens 700 can be 0.8% to 1.2% of the difference in the radius of curvature between the lens layer 710 and the surface layer 720 at the edge portion of the pixel lens 700. Therefore, in the display apparatus according to another embodiment of the present disclosure, the degree of freedom in the material and the forming process of each pixel lens 700 can be improved. For example, in the display apparatus according to another embodiment of the present disclosure, the peeling of each pixel lens 700 from the optical insulating layer 600 can be prevented by using the lens layer 710, and the thickness reduction and the shape change of each pixel lens 700 due to heat can be minimized by using the surface layer 720.

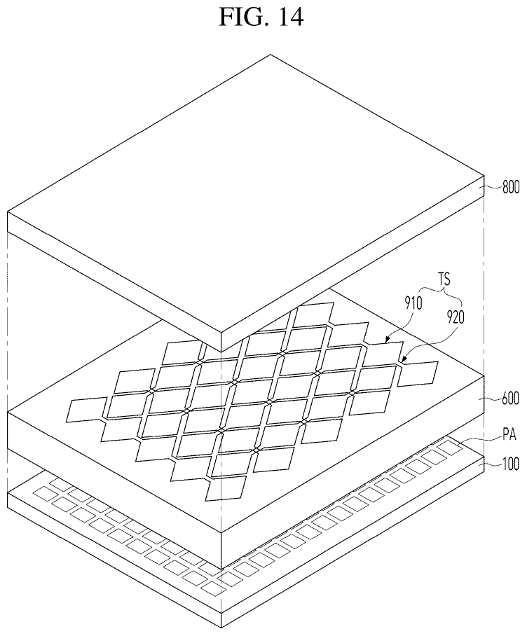

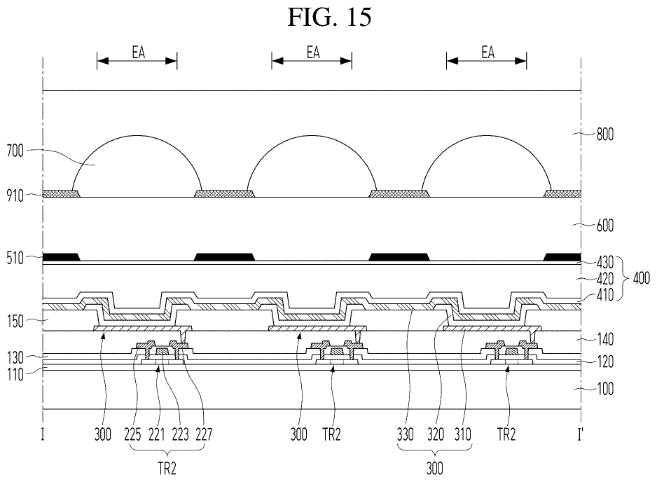

The display apparatus according to the embodiment of the present disclosure is described such that the upper barrier pattern 520 includes a same material as the lower barrier pattern 510. However, in the display apparatus according to another embodiment of the present disclosure, that the upper barrier pattern 520 can include a different material from the lower barrier pattern 510. For example, in the display apparatus according to another embodiment of the present disclosure, a touch sensor TS for sensing a touch of the user or a tool can be disposed between the optical insulating layer 600 and the lens planarization layer 800, as shown in FIGS. 14 and 15.

The touch sensor TS can include touch electrodes 910 and bridge electrodes 920 connecting between the touch electrodes 910. The touch electrodes 910 and the bridge electrodes 920 can include a conductive material. The touch electrodes 910 and the bridge electrodes 920 can include a material capable of blocking light. For example, the touch electrodes 910 and the bridge electrodes 920 can include a metal. At least one of the bridge electrodes 920 can include a different material from the touch electrodes 910. For example, at least one of the bridge electrodes 920 can be disposed on a different layer from the touch electrodes 910.

A lower surface of each touch electrode 910 toward the device substrate 100 can be in direct contact with the upper surface of the optical insulating layer 600. For example, the touch electrodes 910 can be disposed between the optical insulating layer 600 and the lens planarization layer 800. The touch electrodes 910 can be disposed outside the emission area EA defined in each pixel area PA. For example, the touch electrodes 910 can be disposed within the non-emission area. The touch electrodes 910 can overlap the lower barrier pattern 510. The traveling direction of the light emitted from the emission area EA of each pixel area PA can be limited by the touch electrodes 910. For example, in the display apparatus according to another embodiment of the present disclosure, the touch electrodes 910 can function as the upper barrier pattern. That is, in the display apparatus according to another embodiment of the present disclosure, a process of forming the upper barrier pattern can be omitted. Therefore, in the display apparatus according to another embodiment of the present disclosure, the process efficiency can be improved.

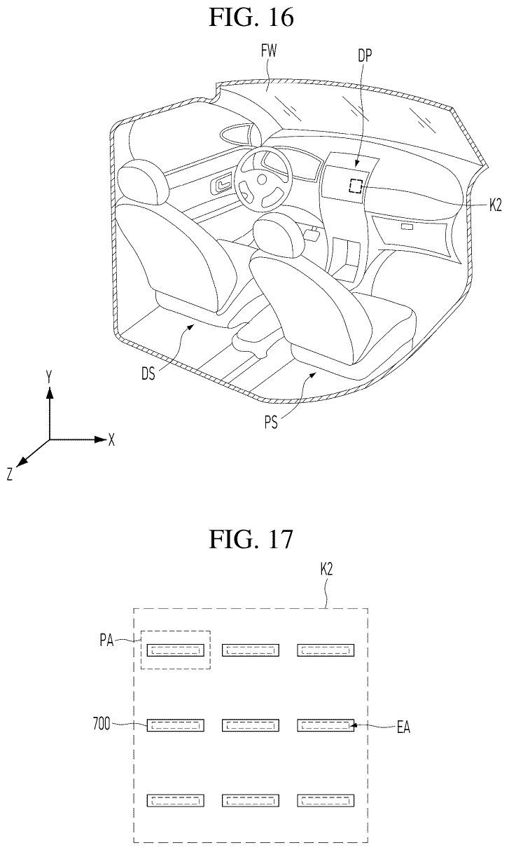

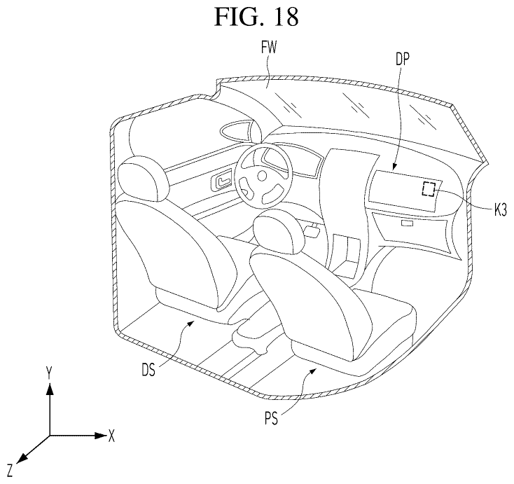

The display apparatus according to another embodiment of the present disclosure can include the display panel DP installed inside a car. For example, in the display apparatus according to another embodiment of the present disclosure, the display panel DP can be disposed between a driver seat DS and a passenger seat PS, as shown in FIGS. 16 and 17. The image realized by the display panel DP can be shared with a driver sitting in the driver seat DS and a passenger sitting in the passenger seat PS. The image realized by the display panel DP can't be reflected by a front wind-shield (FW) of the car. For example, the emission area EA of each pixel area PA and each pixel lens 700 can have a shape of a bar extending in a first direction X. Herein, the first direction X is a direction toward the passenger seat PS from the driver seat DS. The pixel areas PA can be disposed side by side in the first direction X and a second direction Y perpendicular to the first direction X. For example, the front wind-shield FW of the car can be disposed side by side with the display panel DP. A third direction perpendicular to the first direction X and the second direction Y can be a direction toward the driver and the passenger from the display panel DP. Thus, in the display apparatus according to another embodiment of the present disclosure, the image realized by the emission area EA of each pixel area PA and each pixel lens 700 can have a wide viewing angle in the first direction X.

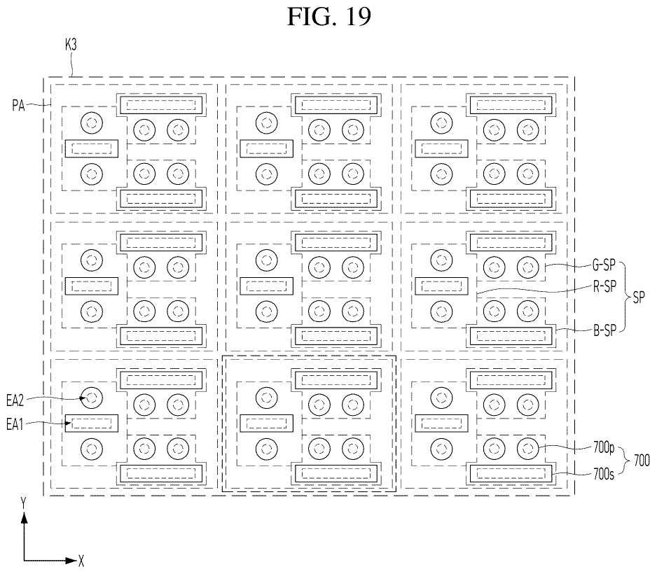

In the display apparatus according to another embodiment of the present disclosure, the image realized by the display panel DP can't be recognized by the driver sitting in the driver seat DS, optionally. For example, in the display apparatus according to another embodiment of the present disclosure, the display panel DP installed in front of the passenger seat PS of the car can realize one of a first image shared with the driver sitting in the driver seat DS and the passenger sitting in the passenger seat PS and a second image that is not recognized by the driver, as shown in FIGS. 18 and 19. Thus, in the display apparatus according to another embodiment of the present disclosure, accidents due to gaze dispersion of the driver can be prevented, while the car is being driven.

A plurality of sub-pixels SP can be disposed within each pixel area PA. For example, a red sub-pixel R-SP realizing a red color, a green sub-pixel G-SP realizing a green color and a blue sub-pixel B-SP realizing a blue color can be disposed within each pixel area PA. A first emission area EA1 and a second emission area EA2 can be defined in each sub-pixel SP. The number of the second emission area EA2 defined in each sub-pixel SP can be different from the number of the first emission area EA1 defined in the corresponding sub-pixel SP. For example, a single first emission area EA1 and two second emission areas EA2 can be defined in each sub-pixel SP.

A plane of the second emission area EA2 can be different from a plane of the first emission area EA1. For example, the first emission area EA1 can have a planar shape of a bar extending in the first direction, and a plane of the second emission area EA2 can have a circular shape. The pixel lenses 700 overlapping with the emission areas EA1 and EA2 of each sub-pixel SP can include a first emission lens 700s having a planar shape corresponding to the first emission area EA1 of each sub-pixel SP and a second emission lens 700p have a planar shape corresponding to the second emission area EA2 of each sub-pixel SP. The first emission area EA1 and the first emission lens 700s of each sub-pixel SP can realize an image having a wider viewing angle in the first direction X than the second emission area EA2 and the second emission lens 700p of each sub-pixel SP. Thus, in the display apparatus according to another embodiment of the present disclosure, one of the first image by the first emission area EA1 and the first emission lens 700s of each sub-pixel SP and the second image by the second emission area EA2 and the second emission lens 700p of each sub-pixel SP can be provided. That is, in the display apparatus according to another embodiment of the present disclosure, the first image having a relative wide viewing angle and the second image having a relative narrow viewing angle can be optionally realized. Therefore, in the display apparatus according to another embodiment of the present disclosure, the difference in color sense of the images having various viewing angles can be minimized.

As a result, the display apparatus according to the embodiments of the present disclosure can comprise the light-emitting device and the pixel lenses stacked on the emission areas of the device substrate, wherein a surface of each pixel lens opposite to the device substrate can have a convex shape, wherein the central portion of the surface of the pixel lens having a convex shape can have a different curvature from the edge portion of the surface of the pixel lens having a convex shape, and wherein at least surface layer of each pixel lens can have the loss tangent (Tan δ) of 0.051 to 0.058. Thus, in the display apparatus according to the embodiments of the present disclosure, the reduction in the thickness of the pixel lens due to heat can be minimized. That is, in the display apparatus according to the embodiments of the present disclosure, the difference in the shape of the pixel lenses due to heat can be reduced. Thereby, in the display apparatus according to the embodiments of the present disclosure, the quality of the image recognized in the inclined direction can be improved. And, in the display apparatus according to the embodiments of the present disclosure, low power driving can be possible, and power consumption can be reduced.

What is claimed is:

1. A display apparatus comprising:
a first light-emitting device on a first emission area of a device substrate;
an optical insulating layer on the first light-emitting device, the optical insulating layer extending beyond the first emission area;
a first pixel lens on the optical insulating layer of the first emission area, a first surface of the first pixel lens opposite to the device substrate having a convex shape; and
a lens planarization layer on the optical insulating layer, the lens planarization layer covering the first surface of the first pixel lens,
wherein a central portion of the first surface of the first pixel lens has a different curvature from an edge of the first surface of the first pixel lens, and
wherein a radius of curvature at the central portion of the first surface is greater than or equal to 98.8% of a radius of curvature at the edge of the first surface.

2. The display apparatus according to claim 1, wherein the edge of the first surface of the first pixel lens is disposed outside the first emission area.

3. The display apparatus according to claim 1, further comprising:
a second light-emitting device between a second emission area of the device substrate and the optical insulating layer; and
a second pixel lens between the optical insulating layer and the lens planarization layer, the second pixel lens overlapping with the second emission area,
wherein a second surface of the second pixel lens toward the lens planarization layer has a convex shape, and
wherein the difference in a radius of curvature between a central portion of the second surface of the second pixel lens and the central portion of the first surface of the first pixel lens is less than or equal to 1.2% of a radius of curvature at the edge of the first surface of the first pixel lens.

4. The display apparatus according to claim 3, wherein the second pixel lens includes a same material as the first pixel lens.

5. The display apparatus according to claim 3, wherein a central portion of the second surface of the second pixel lens has a radius of curvature same as an edge of the second surface of the second pixel lens.

6. The display apparatus according to claim 5, wherein the edge of the second surface of the second pixel lens has the radius of curvature same as the edge of the first surface of the first pixel lens.

7. The display apparatus according to claim 1, further comprising an upper barrier pattern between the optical insulating layer and the lens planarization layer,
wherein the upper barrier pattern is disposed outside the first emission area, and
wherein the edge of the first surface of the first pixel lens overlaps the upper barrier pattern.

8. The display apparatus according to claim 7, further comprising:
an encapsulation structure between the device substrate and the optical insulating layer, the encapsulation structure covering the first light-emitting device; and
a lower barrier pattern between the encapsulation structure and the optical insulating layer, the lower barrier pattern overlapping with the upper barrier pattern,
wherein the lower barrier pattern includes a different material from the upper barrier pattern.

9. A display apparatus, comprising:
a light-emitting device on an emission area of a device substrate;
an optical insulating layer on the light-emitting device, the optical insulating layer extending beyond the emission area;
a pixel lens on the optical insulating layer, the pixel lens including a region overlapping with the emission area; and
a lens planarization layer on the optical insulating layer, the lens planarization layer covering the pixel lens,
wherein the pixel lens includes a lens layer having a convex shape toward the lens planarization layer, and a surface layer disposed between the lens layer and the lens planarization layer, and
wherein the surface layer of the pixel lens has a loss tangent (Tan δ) of 0.051 to 0.058.

10. The display apparatus according to claim 9, wherein a thickness of the surface layer of the pixel lens is smaller than a thickness of the lens layer of the pixel lens.

11. The display apparatus according to claim 9, wherein the lens layer of the pixel lens includes a different material from the surface layer of the pixel lens.

12. The display apparatus according to claim 11, wherein a loss tangent of the lens layer of the pixel lens is different from the loss tangent of the surface layer of the pixel lens.

13. The display apparatus according to claim 9, wherein a thickness of the surface layer at a central portion of the pixel lens is smaller than a thickness of the surface layer at an edge portion of the pixel lens.

14. The display apparatus according to claim 13, wherein a curvature of the lens layer at the central portion of the pixel lens is same as a curvature of the lens layer at the edge portion of the pixel lens.

15. The display apparatus according to claim 9, wherein a difference in a radius of curvature between the surface layer and the lens layer at a central portion of the pixel lens is 0.8% to 1.2% of a difference in a radius of curvature between the surface layer and the lens layer at an edge of the pixel lens.

16. A display apparatus comprising:
a first light-emitting device on a first emission area of a device substrate;
an optical insulating layer on the first light-emitting device, the optical insulating layer extending beyond the first emission area;
upper barrier patterns on the optical insulating layer; and
a first pixel lens on the optical insulating layer of the first emission area, a first surface of the first pixel lens opposite to the device substrate having a convex shape; and
wherein a central portion of the first surface of the first pixel lens has a different curvature from an edge of the first surface of the first pixel lens, and
wherein an edge of the first surface of the first pixel lens extends beyond an edge of one of the upper barrier patterns to overlap the one of the upper barrier pattern.

17. The display apparatus of claim 16, wherein the edge of the first surface of the first pixel lens is in direct contact with a top surface of the one of the upper barrier patterns.

18. The display apparatus according to claim 16, further comprising:
an encapsulation structure between the device substrate and the optical insulating layer, the encapsulation structure covering the first light-emitting device; and
a lower barrier pattern between the encapsulation structure and the optical insulating layer, the lower barrier pattern overlapping with the upper barrier pattern,
wherein the lower barrier pattern includes a different material from the upper barrier pattern.

19. The display apparatus according to claim 16, wherein a radius of curvature at a central portion of the first surface of the first pixel lens is smaller than a radius of curvature at the edge of the first surface of the first pixel lens.

20. The display apparatus according to claim 16, wherein the upper barrier pattern comprises a black dye, and the first pixel lens comprises a polymer material including at least one of a polyester resin, an acrylic resin, a polyurethane resin, a melamine resin, a polyvinyl alcohol resin, and an oxazoline resin.
